(19) United States
(12) Patent Application Publication
(10) Pub. No.: US 2006/0172083 A1
(43) Pub. Date: Aug. 3, 2006

(54) Method of fabricating a thin film

(75) Inventors: Jung-Hyun Lee, Yongin-si (KR); Charig-Soo Lee, Yongin-si (KR); Yoon-Ho Khang, Yongin-si (KR)

Correspondence Address: HARNESS, DICKEY & PIERCE, P.L.C., P.O. BOX 8910, RESTON, VA, 20195, US

(73) Assignee: Samsung Electronics Co., LTD

(21) Appl. No.: 11/341,718

(22) Filed: Jan. 30, 2006

(30) Foreign Application Priority Data
Jan. 31, 2005 (KR) 10-2005-0008753

(51) Int. Cl. C23C 16/00

(52) U.S. Cl. 427/535; 427/248.1

(57) ABSTRACT

Methods of fabricating a thin film. An example method includes forming a GeSbTe thin film on a surface of a substrate by chemically reacting a first precursor including germanium (Ge), a second precursor including antimony (Sb), and a third precursor including tellurium (Te) in a reaction chamber and processing the surface of the GeSbTe thin film with hydrogen plasma. Another example method includes injecting at least one precursor into a reactor chamber and depositing the at least one precursor onto a substrate within the reactor chamber using a chemical vapor deposition process so as to form the thin film.

### PRIORITY STATEMENT

This application claims priority of Korean Patent Application No. 10-2005-0008753, filed on Jan. 31, 2005, in the Korean Intellectual Property Office, the disclosure of which is incorporated herein in its entirety by reference.

### BACKGROUND OF THE INVENTION

1. Field of the Invention

Example embodiments of the present invention relate to a method of fabricating a thin film, and more particularly to a method of fabricating a thin film having reduced impurities.

2. Description of the Related Art

A phase-change material may be selectively converted between crystalline and amorphous states based on an operating temperature. A phase-change material may have a lower resistance when in a crystalline state as compared to the phase-change material in an amorphous state. In the crystalline state, the phase-change material may be characterized as having a systematic or ordered arrangement of atoms. The phase-change material may be reversibly changed between the crystalline and amorphous states such that a conversion from one state to the other may not be permanent. A phase-change random access memory (PRAM) device may be a memory device having characteristics of the phase-change material. A resistance of a PRAM may vary based on a state (e.g., crystalline, amorphous, etc.) of a phase-change material included therein.

A conventional PRAM may include a phase-change film electrically connected to source and drain regions through a contact plug. The PRAM may be configured to operate in accordance with the variation in resistance caused by a state change (e.g., to a crystalline structure, to an amorphous structure, etc.) in the phase-change film.

FIG. 1 illustrates a cross-sectional view of a conventional PRAM 100. Referring to FIG. 1, the conventional PRAM 100 may include a first impurity region 11a and a second impurity region 11b on a semiconductor substrate 10. The conventional PRAM 100 may further include a gate insulating layer 12 contacting the first and second impurity regions 11a and 11b and a gate electrode layer 13. The gate insulating layer 12 and the gate electrode layer 13 may each be stacked on the substrate 10. The first impurity region 11a may function as a source, and the second impurity region 11b may function as a drain.

Referring to FIG. 1, an insulating layer 15 may be formed on the first impurity region 11a, the gate electrode layer 13 and the second impurity region 11b. A contact plug 14 may penetrate the insulating layer 15 to contact the second impurity region 11b. A lower electrode 16 may be mounted on the contact plug 14. A phase-change film 17 and an upper electrode 18 may be formed on the lower electrode 16.

A conventional process for storing data in the PRAM 100 of FIG. 100 will now be described. Heat, which may be measured in Joules, may be generated in an area where the phase-change film 17 contacts the lower electrode 16 due to a current supplied through the second impurity region 11b and the lower electrode 16. The heat generated by the supplied current may adjust a phase state of the phase-change film 17 (e.g., to convert or maintain the phase-change film 17 at one of a crystalline state and an amorphous state), where a resistance corresponding to the phase state of the phase-change film 17 may be indicative of a first logic level (e.g., a higher logic level or logic “1”) or a second logic level (e.g., a lower logic level or logic “0”). The supplied current may be controlled so as to set a phase state of the phase-change film 17.

A conventional phase-change material which may be used in the PRAM 100 may be a compound including germanium (Ge), antimony (Sb), and tellurium (Te) (e.g., GST or GeSbTe). In another example, the phase-change film may be embodied as a chalcogenide material layer.

A power consumption of the conventional PRAM 100 may be reduced by reducing its current consumption. In an example where the PRAM 100 includes GST, a reset current (e.g., a current for transitioning from a crystalline state to an amorphous state) may be higher, thereby consuming higher amounts of power during an operation of the PRAM 100.

A conventional GST thin film may be fabricated with a physical vapor deposition (PVD) process. If a thin film is deposited using the PVD process, it may be difficult to control the thin film growth, the speed of deposition of the thin film may be lower, and the thin film may not have a sufficient density. Additionally, the thin film may be difficult to form in smaller regions. Accordingly, a contact area between a heating unit (e.g., supplying the supply current) and the thing film (e.g., including GST) may increase. Heat loss may thereby be increased due to the increased contact area. The increased heat loss characteristic may cause higher levels of reset current to be applied in the PRAM 100 so as to precipitate a phase state change. Therefore, it may be difficult to employ conventional PRAMs at higher integrations.

### SUMMARY OF THE INVENTION

An example embodiment of the present invention is directed to a method of fabricating a thin film, including forming a GeSbTe thin film on a surface of a substrate by chemically reacting a first precursor including germanium (Ge), a second precursor including antimony (Sb), and a third precursor including tellurium (Te) in a reaction chamber and processing the surface of the GeSbTe thin film with hydrogen plasma.

Another example embodiment of the present invention is directed to a method of fabricating a thin film, including injecting at least one precursor into a reactor chamber and depositing the at least one precursor onto a substrate within the reactor chamber using a chemical vapor deposition process so as to form the thin film.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 illustrates a cross-sectional view of a conventional phase-change random access memory (PRAM).

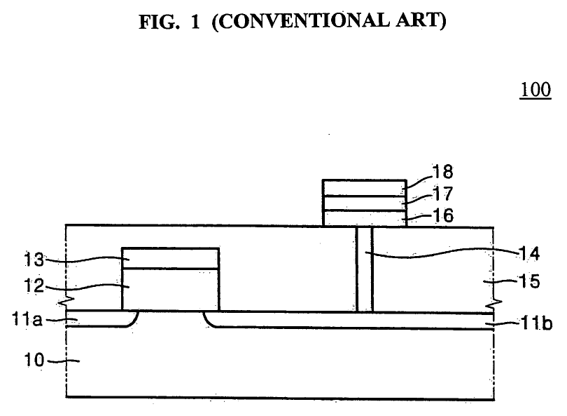

FIGS. 2A through 2D are schematic diagrams illustrating a process of fabricating a thin film according to an example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

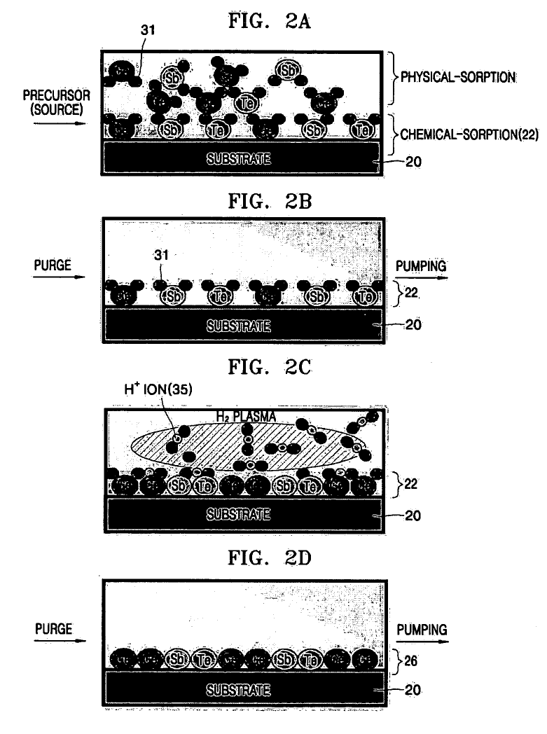

FIGS. 2A through 2D are schematic diagrams illustrating a process of fabricating a thin film according to an example embodiment of the present invention.

In the example embodiment of FIG. 2A, a first precursor including germanium (Ge), a second precursor including antimony (Sb), and a third precursor including tellurium (Te) may be prepared. In an example, the first, second, and third precursors may include Ge[N(CH₃)₂]₄, Sb[N(CH₃)₂]₃, and Te[(CH₃)₂CH]₂, respectively. The first, second, and third precursors may be injected into a reaction chamber (e.g., sequentially injected one after the other, simultaneously or concurrently injected, etc.) and may be chemically deposited on a surface of the substrate 20 of the reaction chamber. In an example, each of the first, second and third precursors may be vaporized before being injected into the reaction chamber. In the reaction chamber, a GeSbTe thin film 22 may be formed on the surface of the substrate 20 through a chemical reaction between the first, second, and third precursors. The GeSbTe thin film 22 may include impurities 31, such as carbon, which may be adsorbed onto the surfaces of Ge, Sb, and Te atoms.

In the example embodiment of FIG. 2A, portions of the first, second and third precursors may not be adsorbed onto the surface of the substrate 20. In an example, these “excess” portions of the first, second and third precursors may be physically adsorbed onto the GeSbTe thin film 22. In an alternative example, the excess portions of the first, second and third precursors may remain in the reactor chamber as a residual gas. In the example embodiment of FIG. 2B, the excess portions of the first, second, and third precursors may be purged (e.g., reduced in presence and/or removed from within the reactor chamber) with an inert gas, such as nitrogen (e.g., N₂).

In the example embodiment of FIG. 2C, the surface of the GeSbTe thin film 22 may be processed with hydrogen plasma. The hydrogen plasma processing may cause the impurities 31 (e.g., including organic molecules such as carbon) previously adsorbed on the Ge, Sb, and Te atoms to be desorbed. The hydrogen plasma may be generated in the reaction chamber so that the impurities 31 remaining on the surfaces of the Ge, Sb and Te atoms may be desorbed and the desorbed impurities 31 may thereafter be adsorbed on hydrogen ions which may separate from the Ge, Sb, and Te atoms. The reaction chamber may then be purged with an inert gas such as nitrogen (e.g., N₂) to remove the separated impurities 31.

In the example embodiment of FIG. 2D, since the impurities 31 may be removed, a resultant GeSbTe thin film 26 may be formed at a higher density and having a lower resistance (e.g., compared to conventional thin films).

In another example embodiment of the present invention, a thin film (e.g., a GeSbTe thin film) may be fabricated using a chemical vapor deposition process, which may be applied at a higher deposition speed as compared to a conventional physical vapor deposition process. The thin film may not include a significant number of impurities on a surface of the thin film because the impurities may be substantially removed (e.g., with hydrogen (e.g., H₂) plasma processing). The thin film may thereby have a higher density and lower resistance as compared to conventional thin films.

In another example embodiment of the present invention, a thin film fabricated using the example process described above with respect to FIGS. 2A-2D may be applied to a write layer of a memory device (e.g., a phase-change memory device (PRAM)). Because a thin film according to an example embodiment of the present invention may have a lower reset current, a memory device (e.g., a PRAM) including the thin film may be more highly integrated, may have a higher storage capacity and/or may operate at higher speeds with reduced power consumption.

Example embodiments of the present invention being thus described, it will be obvious that the same may be varied in many ways. For example, while example embodiments of the present invention have been described above with respect to a GeSbTe thin film, it is understood that other example embodiments of the present invention may be applied to any type of thin film having any well-known chemical composition. In other example embodiments, the GeSbTe thin film may be any phase-change film. For example, the phase-change film may be embodied as a chalcogenide material layer.

In example embodiments, the phase change film may include, arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the phase change film may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the phase change film may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the phase change film is described above as being formed primarily of ternary phase-change chalcogenide alloys, the chalcogenide alloy of the phase change material could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂-S₂ alloy, for example.

In an example embodiment, the phase change film may be made of a transition metal oxide having multiple resistance states, as described above. For example, the phase change material may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The phase change film may be a chemical compound including one or more elements selected from the group consisting of S, Se, Te, As, Sb, Ge, Sn, In and Ag.

Further, while thin films according to example embodiments of the present invention are above-described as being applied in a PRAM, it is understood that other example embodiments of the present invention may apply thin films to any application.

Such variations are not to be regarded as a departure from the spirit and scope of example embodiments of the present invention, and all such modifications as would be obvious to one skilled in the art are intended to be included within the scope of the following claims.

What is claimed is:

1. A method of fabricating a thin film, comprising:
forming a GeSbTe thin film on a surface of a substrate by chemically reacting a first precursor including germanium (Ge), a second precursor including antimony (Sb), and a third precursor including tellurium (Te) in a reaction chamber; and
processing the surface of the GeSbTe thin film with hydrogen plasma.

2. The method of claim 1, wherein the first precursor includes Ge[N(CH₃)₂]₄.

3. The method of claim 1, wherein the second precursor includes Sb[N(CH₃)₂]₃.

4. The method of claim 1, wherein the third precursor includes Te[(CH₃)₂CH]₂.

5. The method of claim 1, wherein forming the GeSbTe thin film includes
chemically adsorbing at least a portion of the first, second and third precursors on the surface of the substrate by injecting the first, second and third precursors into the reaction chamber; and
removing impurities from the reactor chamber with an inert gas.

6. The method of claim 5, wherein each of the first, second, and third precursors is vaporized before being injected into the reaction chamber.

7. The method of claim 5, wherein the first and second precursors are concurrently injected into the reaction chamber.

8. The method of claim 7, wherein the first, second and third precursors are concurrently injected into the reaction chamber.

9. The method of claim 5, wherein the first, second and third precursors are sequentially injected into the reaction chamber.

10. The method of claim 1, wherein processing the surface of the GeSbTe thin film includes
separating impurities on the surface of the GeSbTe thin film from the GeSbTe thin film by adsorbing the impurities onto hydrogen ions after generating hydrogen plasma in the reaction chamber; and
removing the separated impurities by purging the reaction chamber with an inert gas.

11. The method of claim 5, wherein the inert gas includes nitrogen.

12. The method of claim 10, wherein the inert gas includes hydrogen.

13. The method of claim 5, wherein the impurities include carbon.

14. The method of claim 10, wherein the impurities include carbon.

15. A method of fabricating a thin film, comprising:
injecting at least one precursor into a reactor chamber; and
depositing the at least one precursor onto a substrate within the reactor chamber using a chemical vapor deposition process so as to form the thin film.

16. The method of claim 15, wherein the at least one precursor includes at least one of germanium (Ge), antimony (Sb), and tellurium (Te).

17. The method of claim 15, wherein the at least one precursor includes at least one of Ge[N(CH₃)₂]₄, Sb[N(CH₃)₂]₃, and Te[(CH₃)₂CH]₂.

18. The method of claim 15, wherein the chemical vapor deposition process includes
depositing a first portion of the at least one precursor onto the substrate in first locations to generate a temporary thin film;
removing impurities from second locations of the temporary thin film;
depositing a second portion of the at least one precursor onto the substrate in the second locations to generate the thin film, the thin film having a higher precursor density than the temporary thin film.

19. The method of claim 18, wherein the impurities include carbon.
